(19) United States
(12) Patent Application Publication
(10) Pub. No.: US 2017/0025585 A1
(43) Pub. Date: Jan. 26, 2017

(54) Fluorescent Strip and Light-Emitting Diode (LED) Packaging Module Employing Same

(71) Applicant: SHENZHEN CHINA STAR OPTOELECTRONICS TECHNOLOGY CO. LTD, Shenzhen, Guangdong (CN)

(72) Inventor: Yong FAN, Shenzhen, Guangdong (CN)

(21) Appl. No.: 14/647,116

(22) PCT Filed: Jul. 10, 2014
(86) PCT No.: PCT/CN2014/081962

§ 371 Date: May 25, 2015

(30) Foreign Application Priority Data
Apr. 18, 2014 (CN) 201410158108.3

(51) Int. Cl. H01L 33/50; H01L 33/64; H01L 25/075

(52) U.S. Cl. CPC H01L 33/505; H01L 25/0753; H01L 33/502; H01L 33/642; H01L 2933/0083; H01L 2933/0091; G02B 6/0025

(57) ABSTRACT

The invention provides a fluorescent strip, which covers a luminous body, wherein the fluorescent strip includes a fluorescent powder layer and at least two protective layers; and the fluorescent powder layer is sandwiched between the two protective layers, so that the falling of fluorescent powder is avoided, a function of protecting and limiting the fluorescent powder is realized, and the fluorescent powder is uniformly laid on a surface of the luminous body. The fluorescent strip further includes a light converging layer, wherein the light converging layer covers the outer protective layer; and light emitted from the luminous body sequentially passes through the inner protective layer, the fluorescent power layer, the outer protective layer and the light converging layer, and is converged into light rays through the light converging layer.

### FIELD OF THE INVENTION

The invention relates to a luminous component for a liquid crystal display, and particularly discloses a fluorescent strip and a Light-Emitting Diode (LED) packaging module employing the same.

### BACKGROUND OF THE INVENTION

At present, an LED is substantially packaged in the same packaging body by virtue of a blue light chip and fluorescent powder, but energy which is not converted into optical energy can be converted into heat energy when the light is emitted by the blue light chip, so that own luminous efficiency of the blue light chip is reduced, the conversion efficiency can also be reduced along with a temperature rise of the fluorescent powder in the packaging body, and the overall luminous efficiency of the LED is finally reduced. The fluorescent powder has a temperature quenching effect, so that the conversion efficiency of the fluorescent powder can be reduced along with the temperature rise, and a luminescent spectrum is redshifted; and such an effect is particularly remarkable for Quantum Dots (QDs) fluorescent powder with a narrower luminescent spectrum Full Width at Half Maximum (FWHM).

During a conventional application of the QDs fluorescent powder, the problem of temperature quenching can be solved mainly by two solutions:

first, QDs fluorescent powder is coated on a film, such as a Quantum Dot Enhancement Film (QDEF) developed by the 3M Company; and

second, as shown in FIG. 1, the QDs fluorescent powder is packaged in a glass lamp tube.

In the second scheme, an emitting direction of fluorescent light emitted by the QDs fluorescent powder which is re-excited by blue light is undetermined, so that a light form emitted from the glass lamp tube is scattered, the ratio of wide-angle light is high, the efficiency of the light re-entering a light guide plate is reduced, and the light coupling efficiency is low.

### SUMMARY OF THE INVENTION

In order to solve the problem above, the invention provides a fluorescent strip capable of gathering light within a wide viewing angle to improve the light coupling efficiency and eliminating total reflection in a luminous body to improve the luminous efficiency.

Another aim of the invention is to provide an LED packaging module employing a fluorescent strip so as to improve the luminous efficiency of an LED and improve light converging effects.

The invention provides a fluorescent strip, which covers a luminous body, wherein the fluorescent strip includes a fluorescent powder layer and at least two protective layers; and the fluorescent powder layer is sandwiched between the two protective layers, so that the falling of fluorescent powder is avoided, a function of protecting and limiting the fluorescent powder is realized, and the fluorescent powder is uniformly laid on a surface of the luminous body.

Preferably, the protective layers include an outer protective layer and an inner protective layer. The fluorescent strip further includes a light converging layer, wherein the light converging layer covers the outer protective layer; and light emitted by the luminous body sequentially passes through the inner protective layer, the fluorescent power layer, the outer protective layer and the light converging layer, and is converged into light rays through the light converging layer.

Preferably, the light converging layer consists of a plurality of light converging single bodies which are closely arranged, and is saw tooth-shaped. Each light converging single body is triangular, prismatic or semi-cylindrical. The light rays emitted by the luminous body are converged and gathered by the saw tooth-shaped light converging layer, so that the light converging effects are improved.

Preferably, an emergent surface of each light converging single body is prism-shaped, so that the emitted light rays are refracted to achieve light ray converging effects when passing through the emergent surfaces.

Preferably, a vertex angle of each light converging single body is ranged from 30 to 120 degrees, preferably 90 degrees, and when the vertex angle is 90 degrees, a light acceptance function is the best, and a light form is the narrowest.

Preferably, the light converging layer is made from MS, Polymethyl Methacrylate (PMMA) or silica gel, and the protective layers are made from MS, PMMA or silica gel.

The invention also provides an LED packaging module, which includes:

a heat conduction substrate;

a plurality of LED chips, welded on the heat conduction substrate; and

a fluorescent strip, which covers the LED chips and includes a fluorescent powder layer, at least two protective layers and a light converging layer, wherein the protective layers include an outer protective layer and an inner protective layer; the fluorescent powder layer is sandwiched between the two protective layers, so that the falling of fluorescent powder is avoided; the light converging layer covers the outer protective layer, and light emitted by the LED chips sequentially passes through the inner protective layer, the fluorescent power layer, the outer protective layer and the light converging layer, and is converged into light rays through the light converging layer.

Compared with the prior art, the fluorescent strip of the invention has the following advantages:

1) the fluorescent powder layer is covered and protected by the protective layers, and is prevented from seepage, and protection and packaging functions are realized;

2) the fluorescent strip is attached to the LED chips of the LED packaging module, and the fluorescent powder is not required to be coated in the LED packaging module, so that an overall structure of the LED packaging module is improved, a manufacturing procedure is simplified, packaging is simplified, and the production efficiency is improved; and

3) the light converging layer is additionally arranged on the outer side of the fluorescent strip, and is saw tooth-shaped, and the light rays emitted by the LED chips are refracted and converged by the light converging single bodies, so that the light emitted within a large angle can be more gathered, the ratio of the light emitted within the large angle is reduced, the aim of converging the light rays is fulfilled, the emitting direction of fluorescent light is determined, the fluorescent light enters a light guide plate at a small angle, and the light coupling efficiency of the light rays entering a liquid crystal display is improved.

### BRIEF DESCRIPTION OF THE DRAWINGS

FIG. 1 is a structure diagram of a conventional fluorescent strip;

FIG. 2 is a structure diagram of a fluorescent strip of the invention;

FIG. 3 is an exploded view of an LED packaging module of the invention;

FIG. 4 is a schematic diagram of light emission of light converging single bodies of a fluorescent strip of the invention; and

FIG. 5 is a stereogram of a light converging layer of a fluorescent strip of the invention.

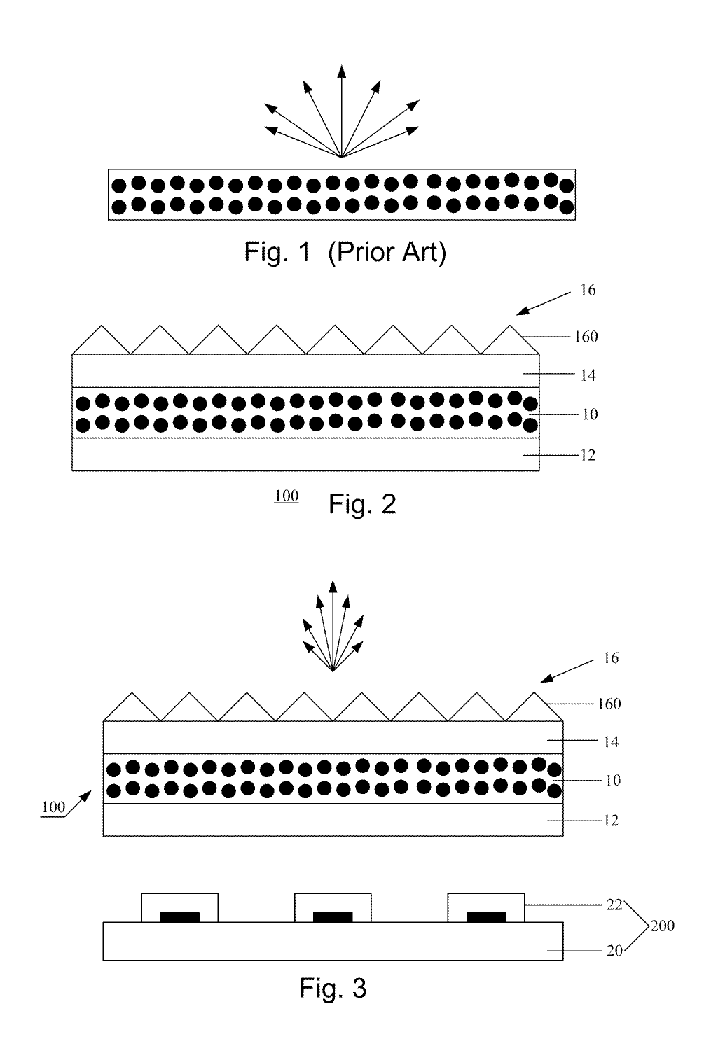

### DETAILED DESCRIPTION OF THE PREFERRED EMBODIMENTS

In order to improve the luminous efficiency of the LED packaging module, improve the conversion efficiency of the fluorescent powder, determine the light-emitting direction of the fluorescent powder and gather the light, as shown in FIG. 2, the invention provides a fluorescent strip 100, covering a luminous body 200, wherein the fluorescent strip 100 includes a fluorescent powder layer 10 and at least two protective layers; and the fluorescent powder layer 10 is sandwiched between the two protective layers, so that the falling of the fluorescent powder is avoided, a function of protecting and limiting the fluorescent powder is realized, and the fluorescent powder is uniformly laid on a surface of the luminous body 200.

In one embodiment of the invention, there are two protective layers, i.e. an inner protective layer 12 and an outer protective layer 14, wherein widths of the inner protective layer 12, the outer protective layer 14 and the fluorescent powder layer 10 are equal; and the fluorescent powder layer 10 is sandwiched between the inner protective layer 12 and the outer protective layer 14. The fluorescent powder layer 10 is uniformly provided with the fluorescent powder, wherein the fluorescent powder can be yellow powder in Yttrium Aluminum Garnet (YAG) fluorescent powder, nitride fluorescent powder and silicate fluorescent powder, and can also be red fluorescent powder in Nitride fluorescent powder and silicate fluorescent powder, and can also be red fluorescent powder in QDs; the QDs in the fluorescent powder layer are wrapped by silica gel; and the fluorescent powder is not limited by the abovementioned materials.

In another embodiment of the invention, the fluorescent strip 100 further includes a light converging layer 16, wherein the light converging layer 16 covers the outer protective layer 14, and light emitted by the luminous body 200 sequentially passes through the inner protective layer 12, the fluorescent power layer 10, the outer protective layer 14 and the light converging layer 16, and is converged into light rays through the light converging layer 16. The light converging layer 16 consists of a plurality of light converging single bodies 160 which are closely arranged, and is saw tooth-shaped. Each light converging single body 160 is triangular, prismatic or semi-cylindrical. The light rays emitted by the luminous body 200 are converged and gathered by the saw tooth-shaped light converging layer 16, so that light converging effects are improved. As shown in FIG. 2 and FIG. 3, a vertex angle of each light converging single body is ranged from 30 to 120 degrees, preferably 90 degrees, and when the vertex angle is 90 degrees, a light acceptance function is the best, and a light form is the narrowest. Light paths formed by the light emitted by the fluorescent powder layer are scattered, and the ratio of light emitted within a large angle is high; the fluorescent strip of the invention reflects light through each light converging single body 160 of the light converging layer 16, so as the scattered light rays are refracted by a plurality of light converging single bodies 160 to be converged and gathered, and particularly, the light emitted within the large angle is gathered and narrowed, so that the ratio of the light emitted within the large angle is reduced, and the light rays can enter a light guide plate at a small angle when entering a liquid crystal display; and therefore, the light coupling efficiency of the light entering the liquid crystal display is improved.

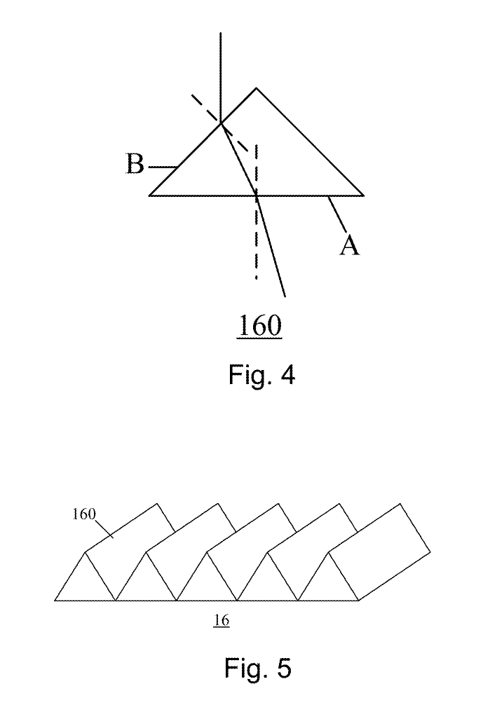

As shown in FIG. 4 and FIG. 5, an emergent surface of each light converging single body 160 has a prism-shaped structure, and the light rays are emitted into the light converging single bodies from incident surfaces, and then are refracted by the prism-shaped emergent surfaces so as to be gathered and converged.

Preferably, the light converging layer is made from MS, PMMA or silica gel, and the protective layers are made from MS or PMMA. The light converging layer or the protective layers are low in refraction index and high in light transmission; and therefore, by the materials, the luminous efficiency of the light in a light guide strip can be effectively improved, and a light converging microstructure can be manufactured by adopting injection molding and imprinting processes. In addition, due to the adoption of a material such as silica gel with low water and oxygen permeability, the service life of the fluorescent powder can be prolonged.

The invention also provides an LED packaging module, which includes:

a heat conduction substrate 20;

a plurality of LED chips 22, welded on the heat conduction substrate 20; and

a fluorescent strip 100, which covers the LED chips 22 and includes a fluorescent powder layer 10 and at least two protective layers, wherein the fluorescent powder layer 10 is sandwiched between the two protective layers, so that the falling of fluorescent powder is avoided.

The protective layers include an inner protective layer 12 and an outer protective layer 14, and the fluorescent powder layer 10 is sandwiched between the inner protective layer 12 and the outer protective layer 14. The fluorescent strip 100 further includes a light converging layer 16, wherein the light converging layer 16 covers the outer protective layer 14, and light emitted by the LED chips 22 sequentially passes through the inner protective layer 12, the fluorescent power layer 10, the outer protective layer 14 and the light converging layer 16, and is converged into light rays through the light converging layer 16 to realize the converging of the light emitted within a large angle and improve the light coupling efficiency; and total reflection in the LED packaging module is damaged by the light converging layer 16, so that the luminous efficiency is effectively improved, and the conversion efficiency of the fluorescent powder is improved.

What is claimed is:

1. A fluorescent strip, covering a luminous body, wherein the fluorescent strip comprises a fluorescent powder layer and at least two protective layers; the fluorescent powder layer is sandwiched between the two protective layers, so that the falling of fluorescent powder is avoided; the protective layers comprise an outer protective layer and an inner protective layer; the fluorescent strip further comprises a light converging layer, and the light converging layer covers the outer protective layer; and light emitted from the luminous body sequentially passes through the inner protective layer, the fluorescent power layer, the outer protective layer and the light converging layer, and is converged into light rays through the light converging layer.

2. The fluorescent strip according to claim 1, wherein the light converging layer consists of a plurality of light converging single bodies which are closely arranged.

3. The fluorescent strip according to claim 2, wherein each light converging single body is triangular, prismatic or semi-cylindrical.

4. The fluorescent strip according to claim 3, wherein an emergent surface of each light converging single body is prism-shaped.

5. The fluorescent strip according to claim 4, wherein a vertex angle of each light converging single body is ranged from 30 to 120 degrees.

6. The fluorescent strip according to claim 5, wherein the vertex angle of each light converging single body is 90 degrees.

7. The fluorescent strip according to claim 2, wherein the light converging layer is saw tooth-shaped.

8. The fluorescent strip according to claim 2, wherein the light converging layer is made from MS, polymethyl methacrylate or silica gel, and the protective layers are made from MS or polymethyl methacrylate.

9. A Light-Emitting Diode (LED) packaging module, comprising:
a heat conduction substrate;
a plurality of LED chips, welded on the heat conduction substrate; and
a fluorescent strip, which covers the LED chips and comprises a fluorescent powder layer, at least two protective layers and a light converging layer, wherein the protective layers comprise an outer protective layer and an inner protective layer; the fluorescent powder layer is sandwiched between the two protective layers, so that the falling of fluorescent powder is avoided; and the light converging layer covers the outer protective layer, and light emitted from the LED chips sequentially passes through the inner protective layer, the fluorescent power layer, the outer protective layer and the light converging layer, and is converged into light rays through the light converging layer.

10. A fluorescent strip, covering a luminous body, wherein the fluorescent strip comprises a fluorescent powder layer and at least two protective layers; and the fluorescent powder layer is sandwiched between the two protective layers, so that the falling of fluorescent powder is avoided.

11. The fluorescent strip according to claim 10, wherein protective layers comprise an outer protective layer and an inner protective layer; the fluorescent strip further comprises a light converging layer, and the light converging layer covers the outer protective layer; and light emitted from the luminous body sequentially passes through the inner protective layer, the fluorescent power layer, the outer protective layer and the light converging layer, and is converged into light rays through the light converging layer.

12. The fluorescent strip according to claim 11, wherein the light converging layer consists of a plurality of light converging single bodies which are closely arranged.

13. The fluorescent strip according to claim 12, wherein each light converging single body is triangular, prismatic or semi-cylindrical.

14. The fluorescent strip according to claim 13, wherein an emergent surface of each light converging single body is prism-shaped.

15. The fluorescent strip according to claim 14, wherein a vertex angle of each light converging single body is ranged from 30 to 120 degrees.

16. The fluorescent strip according to claim 15, wherein the vertex angle of each light converging single body is 90 degrees.

17. The fluorescent strip according to claim 12, wherein the light converging layer is saw tooth-shaped.

18. The fluorescent strip according to claim 12, wherein the light converging layer is made from MS, polymethyl methacrylate or silica gel, and the protective layers are made from MS or polymethyl methacrylate.
